(19) United States
(12) Patent Application Publication
(10) Pub. No.: US 2020/0251357 A1
(43) Pub. Date: Aug. 6, 2020

(54) METHOD AND APPARATUS FOR SUPPLYING GAS TO A CHUCK

(71) Applicants: Edwards Limited, Burgess Hill (GB); Edwards Vacuum LLC, Sanborn, NY (US)

(72) Inventors: George Vincent Courville, Sanborn, NY (US); Declan Scanlan, Celbridge (IE); Christopher Mark Bailey, Burgess Hill (GB)

(21) Appl. No.: 16/265,556

(22) Filed: Feb. 1, 2019

(51) Int. Cl. H01L 21/67; H01L 21/683

(52) U.S. Cl. CPC H01L 21/67109; H01L 21/683; H01L 21/67017

(57) ABSTRACT

An apparatus and method for supplying gas to improve heat transfer between a wafer and chuck is disclosed. The apparatus comprises at least one processing chamber comprising a chuck for mounting a semiconductor wafer; at least one processing chamber vacuum pump for evacuating the at least one processing chamber; and a gas supply apparatus for supplying gas to the chuck for providing cooling to a backside of the semiconductor wafer, the gas supply apparatus comprising: a conduit for connecting to a gas supply; a gas supply apparatus vacuum pump, an inlet of the gas supply apparatus vacuum pump being connected to the conduit; the conduit comprising a junction connecting to a further conduit the further conduit being in fluid communication with the chuck.

### FIELD

The embodiments relate to a method and apparatus for supplying gas to a chuck within a process chamber to improve thermal transfer between the chuck and a wafer mounted thereon.

### BACKGROUND

Many wafer chucks use helium as the heat transfer medium between the chuck and the wafer for wafer temperature control. The Helium flows end up being mixed with the chamber exhaust gases and are pumped out through the vacuum system to the abatement system and are exhausted from the fab. This is wasteful on Helium use and adds to the gases being exhausted.

The discussion above is merely provided for general background information and is not intended to be used as an aid in determining the scope of the claimed subject matter. The claimed subject matter is not limited to implementations that solve any or all disadvantages noted in the background.

### SUMMARY

A first aspect provides a gas supply apparatus for supplying gas to a chuck within a processing chamber, said gas being for improving heat transfer between said chuck and a wafer mounted on said chuck, said gas supply apparatus comprising: a conduit for connecting to a gas supply; a gas supply apparatus vacuum pump, an inlet of said gas supply apparatus vacuum pump being connected to said conduit; wherein said conduit comprises a junction connected to a further conduit said further conduit being configured to supply said gas to said chuck.

The semiconductor industry uses a gas as a heat transfer medium between the chuck and the wafer in semiconductor processing. This gas has conventionally been Helium. Helium has been selected for this because it is inert and therefore does not affect the process, it has very good thermal conductivity and its low viscosity allows it to flow through small channels. However, the supply and hence the price of Helium is subject to various geopolitical influences which have caused concern in the semiconductor industry and interest in ways of reducing the demand. Furthermore Helium is sourced as a byproduct of hydrocarbon production—which makes the supply dependant on factors relating to hydrocarbon supply. Whilst in some areas it may be possible to simply reduce the Helium flow rate, that may not possible where it is used for wafer temperature control. Temperature has a critical influence on the wafer process and critical dimension uniformity so the flow rate is defined by the required performance. Furthermore, as the need for uniformity increases with both smaller features and increasingly complex structures (i.e 3D) the likelihood is that flow rates increase.

A further way of reducing the quantity of heat transfer gas such as Helium would be to recover at least some of the gas that is used. However, recovering the gas from the exhaust gases from the etch process which are inherently corrosive is difficult and in general not cost effective. The inventors of the present invention recognised that the capturing of gas before it becomes entrained in the process exhaust gas would enable it to be collected in a simpler and cheaper way.

They have addressed this by providing an additional dedicated vacuum pump to pump the gas flow and avoid or at least inhibit its contamination with process gases. There is a prejudice in the field for providing additional vacuum pumps. However, the inventors recognised that the pump could be a relatively cost effective solution, with the requirements of relatively low capacity and not too high a vacuum. Such a solution does however, require a change to the design of the process tool with the provision of an additional vacuum port connection.

The provision of a gas such as Helium to a chuck in a semiconductor processing chamber, can be achieved by maintaining the pressure of the gas in a conduit at a predetermined pressure and having a side conduit or static line extending from the channel to the back side of the chuck. The gas travels through distribution channels in the chuck to the back side of a wafer mounted on the chuck. Typically the gas pressure in the channels in the chuck, are maintained at around 5-10 Torr, which is limited both to control the amount that leaks into the chamber as well to avoid interfering with the wafer clamping. The design intent is that there is no flow in the chuck but there is inevitably some leakage. It is important that the pressure is maintained and this is achieved in the current implementations by having a substantially constant flow in the conduit that feeds the static line or conduit attached at the junction to the chuck. In some embodiments the constant flow rate is in the order of 10 sccm (standard cubic centimetres per minute).

Conventionally the flow in the supply conduit spills into the chamber exhaust line connected to the vacuum foreline of the pumps evacuating the vacuum chambers. The application proposes modifying the design of the chamber exhaust so that the gas is not dissipated into the process chamber but is ducted to a port connected to a suitable dedicated vacuum pump which can pressurize it. In embodiments the recovered gas can be pumped either to a collection vessel and/or a purification system. From there it can either be returned to the process chamber in a closed loop system or taken to a remote location for purification.

In some embodiments, said conduit comprising a pressure regulator for regulating a pressure within said conduit.

It is important in the control of the flow of gas to the chuck that the pressure in the conduit is maintained substantially constant at a selected pressure and this is achieved in some embodiments by a pressure regulator. In effect the regulator controls the pressure in the conduit and thus, in the further conduit or static feed line and hence under the wafer. In this regard, the gas flow through the static feed line or further conduit into the chuck is governed by the flow past the edge of the wafer into the chamber. This flow rate is intended to be as low as possible—but in some circumstances there may be some beneficial effect to having a small flow to manage damage to the wafer edge from the plasma etch. It may also be that there is a practical minimum design limit to the flow rate below which the differences in flow cause noticeable variability at the wafer edge. In any case, the majority of the flow follows a path that result in it entering the chamber exhaust flow—not the chamber—so downstream of the chamber exhaust flow. The idea is to establish a constant pressure under the wafer and it is to this end that the pressure regulator controls the pressure in the conduit.

In some embodiments, said pressure regulator comprises a back pressure regulator for maintaining a defined pressure within said conduit upstream of said pressure regulator.

This pressure regulator may be located upstream or downstream of the junction.

It has been found, depending on the design of the system, such as the pressure the gas supply system is regulated to, how it is connected to the chamber and the expected behaviour in case of wafer removal or some failure, that it may be more appropriate to locate the pressure regulator upstream of the junction rather than in the conventional downstream position.

The gas supplied to the backside of the wafer is selected to be a gas with good thermal transfer properties, enabling heat transfer between the cooled chuck and the wafer, and thereby providing cooling to the wafer and in particular, the backside of the wafer that is the side of the wafer closest to the chuck. In some embodiments, the gas comprises Helium. Helium acts as an effective cooling gas owing to its high thermal conductivity. Furthermore, it is also inert and thus, does not cause undue problems when mixing with the process exhaust gases.

In some embodiments, said apparatus comprises a gas collector for collecting said gas output from said gas supply vacuum pump.

By having a dedicated vacuum pump that is isolated from the chamber exhaust for pumping the gas flow in the conduit, the gas can be captured and collected for later use, thereby reducing the amount of gas required and/or exhausted to the environment.

In some embodiments, said apparatus comprises a compressor for compressing said gas output from said gas supply vacuum pump prior to supplying said gas to said gas collector.

In order to more effectively collect the low pressure gas it may be helpful to compress the gas prior to collecting it.

In some embodiments, said apparatus comprises a purifier configured to receive said gas output from said gas supply apparatus vacuum pump.

It may be desirable to purify the gas collected to remove any impurities entrained in the gas flow.

In some embodiments, said purifier is configured to output purified gas to said channel upstream of said junction and to output extracted impurities to an exhaust of said apparatus.

The purified gas may be recycled to the system thereby reducing the amount of gas required from the gas supply. Any impurities may be exhausted from the system.

In some embodiments, said apparatus comprises a plurality of conduits for supplying gas to a plurality of chucks within a plurality of processing chambers, said gas supply apparatus comprising at least one of said gas supply apparatus vacuum pumps, each of said conduits being connected to an inlet of said at least one gas supply apparatus vacuum pump, gas output from said at least one gas supply apparatus vacuum pump being combined prior to being supplied to one of a purifier, compressor or gas collector.

The gas supply system may operate to supply gas to a single processing chamber, alternatively it may supply gas to a number of processing chambers within a system. In such a case the gas purifying, collecting and/or recycling systems may be combined for all the chambers thereby reducing the overall cost of the system. In such a multiple chamber system there may be a single pump pumping a plurality of conduits for supplying the gas to multiple chambers, or there may be a plurality of pumps, in some cases one for each chamber. Each conduit may have its own pressure regulator.

In some embodiments, said apparatus comprises a ballast gas supply for supplying a ballast gas to said inlet of said gas supply apparatus vacuum pump.

One potential problem arising with the dedicated vacuum pump particularly where the gas pumped is a small molecule gas such as Helium, is that this gas may be difficult to pump—the small molecule having a tendency to leak back through clearances within the pump requiring additional pumping capacity and power to compensate for the resultant inefficiency. This is mitigated in embodiments by the addition of a ballast gas supplied to the vacuum pump inlet. This gas may have a larger molecule thereby improving pumping efficiency. One choice might be Nitrogen which is an inert gas with a larger molecule. The ballast gas can be removed from the flow downstream of the pump by a filter/sieve and routed to the process exhaust line.

In some embodiments, said apparatus comprises a cooler configured to cool at least a portion of said conduit downstream of said junction.

An alternative/additional way of mitigating the pumping inefficiency would be to cool the gas and in some embodiments the pump too.

In some embodiments, said cooler comprises a thermal transfer device for transferring heat between said conduit and a cooling system for cooling said chuck.

In some embodiments, said cooler comprises a thermal transfer device for transferring heat between a cooling system for cooling said chuck and at least one of said gas supply vacuum pump and said conduit.

In some cases the apparatus may make use of the chiller or cooler system that is already included in the process apparatus for cooling the chuck. Adding heat transfer means such as a heat exchanger supplied with cooling fluid from the chuck cooling system to the conduit immediately upstream of the vacuum pump and surrounding at least a portion of the vacuum pump provides an effective and low cost cooling means to improve the pumping effectiveness of the vacuum pump. This may be particularly effective where the wafer is cooled to very low temperatures (i.e cryo etch where approximately −70° C. is anticipated).

A second aspect provides, an apparatus comprising at least one processing chamber comprising a chuck for mounting a semiconductor wafer; at least one processing chamber vacuum pump for evacuating said at least one processing chamber; and a gas supply apparatus according to a first aspect for supplying gas to said chuck for providing cooling to a backside of said semiconductor wafer.

A third aspect provides, a method of supplying gas to a chuck within an evacuated processing chamber in order to improve heat transfer between said check and a semiconductor wafer mounted thereon, said method comprising: pumping using a dedicated vacuum pump a gas from a gas supply through a conduit connected to said gas supply, said conduit comprising a junction connected to a further conduit said further conduit supply said gas to said chuck; and regulating a pressure within said conduit to maintain a pressure of said gas at said junction at a predetermined value.

Further particular and preferred aspects are set out in the accompanying independent and dependent claims. Features of the dependent claims may be combined with features of the independent claims as appropriate, and in combinations other than those explicitly set out in the claims.

Where an apparatus feature is described as being operable to provide a function, it will be appreciated that this includes an apparatus feature which provides that function or which is adapted or configured to provide that function.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

Embodiments of the present invention will now be described further, with reference to the accompanying drawings, in which:

FIG. 1 shows a gas supply system for supplying gas to a chuck with collection vessel for collecting gas;

FIG. 2 shows a gas supply system for supplying gas to a chuck with closed loop recirculation;

FIG. 3 shows a gas supply system for supplying gas to a chuck with closed loop recirculation and gas ballast; and

FIG. 4 shows a gas supply system for supplying gas to a chuck with closed loop recirculation and cooling for pump and gas line.

### DETAILED DESCRIPTION

Before discussing the embodiments in any more detail, first an overview will be provided.

Conventionally the gas supply that feeds the chuck is routed to the chamber exhaust—either upstream or downstream of the turbo pump (If fitted). Pressure is controlled by a back pressure regulator which requires a flow to operate.

Embodiments of the application provide a vacuum pump, which may be a roots pump or a combination drag/regen pump such that the Helium (or other gas) flow may be at least partially isolated from the process exhaust allowing the gas to be compressed and pumped to either a collection vessel in which it is captured and/or to a purification system which then directs the purified helium back to the chuck. The regulator may in some embodiments be relocated to upstream of the connection to the chuck.

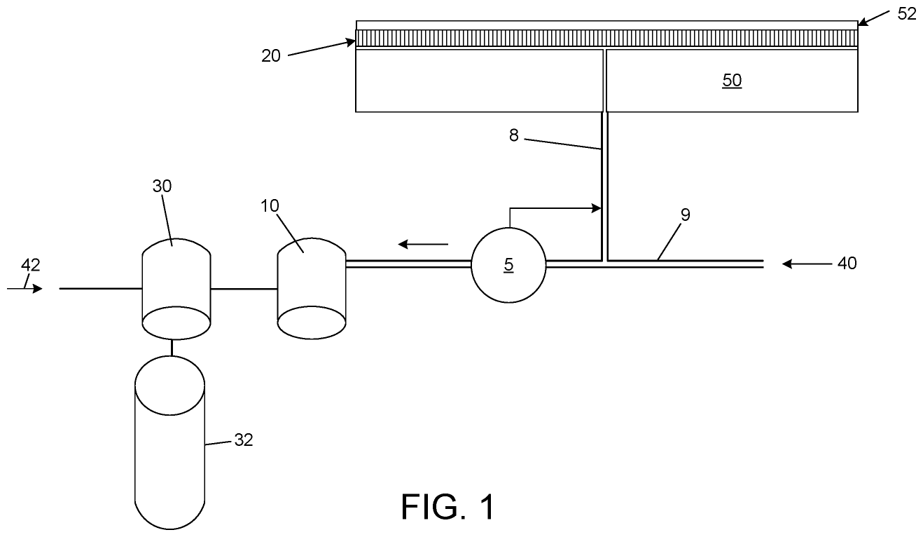

FIG. 1 shows a gas supply system for supplying a gas to a chuck, to allow improved heat transfer between the cooled chuck 50 and wafer 52 mounted thereon. The gas 40 supplied to the chuck is distributed through channels 20 in the chuck to lie between the wafer 52 and chuck 50. Gas 40 is supplied to a conduit 8 and pumped by vacuum pump 10 past a junction to a further conduit 9 which is connected to the back side of chuck 5. The gas in conduit 8 flows through a pressure regulator 5. The gas pumped by vacuum pump 10 is output to compressor 30 and then to collection vessel 32.

The system is configured such that the flow of gas in the conduit 8 is maintained at a substantially constant flow rate with the pressure maintained in the conduit at a predetermined value. In this embodiment the pressure is maintained by pressure regulator 5. In other embodiments the pressure may be maintained by other means such as a restriction in the conduit and the vacuum pump pumping at a constant rate. The predetermined pressure is selected such that the flow of gas to the chuck is low such that only a small amount of gas leaks into the process exhaust but a sufficient quantity of gas is retained in the distribution channels 20 to maintain the heat transfer at acceptable levels. This predetermined pressure will depend on the vacuum in the processing chamber but is typically 5-10 Torr.

In this embodiment the collection vessel 32 is a gas cylinder which in this embodiment is pressurized to between 400 psig and 2400 psig. In some embodiments, this pressure may be generated by the vacuum pump 10 itself, in other embodiments such as the one shown, a separate compressor 30 is used. In this embodiment the compressor 30 and the collection vessel 32 are shared with other process chambers or process tools.

As noted above in this embodiment the gas collection system 30, 32 collects gas from multiple conduits supplying gas to multiple processing chambers. Thus, in addition to the gas 40 through conduit 8, there is also gas 42 supplied from a further conduit (not shown) connected to a further chuck (not shown). Although only one other gas supply is shown, there may be multiple chucks and conduits whose gas supply is collected by gas collection system 30, 32. In this embodiment each processing chamber and chuck has its own vacuum pump 10 and pressure regulator 5 for controlling the pressure in the conduits 8, in other embodiments, multiple conduits connected to multiple chambers may be pumped by one or more shared vacuum pumps 10.

The collected gas can then be taken to another location for repurification and repackaging. If the gas is directly routed to a purifier it can then be reintroduced to the chuck, having been mixed with sufficient fresh top-up gas to replace that which was lost to the chamber or to the purifier.

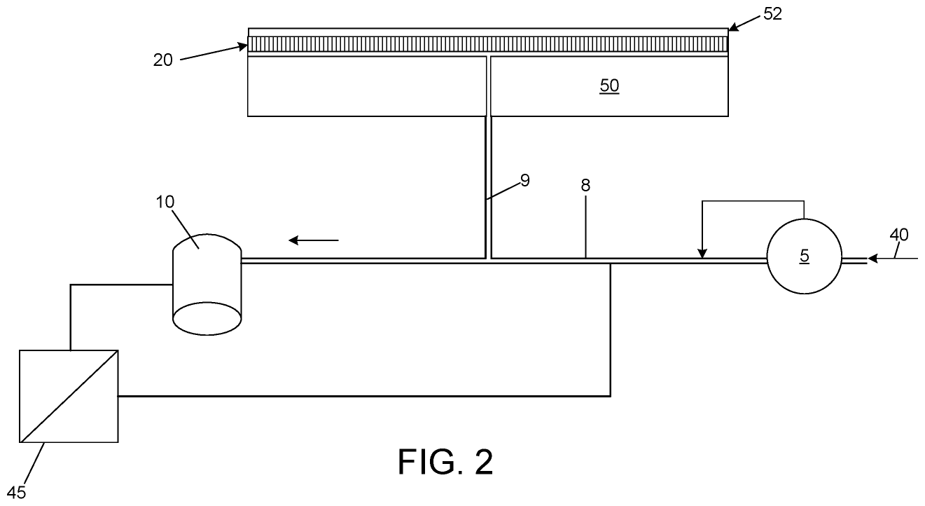

FIG. 2 shows a further embodiment that is similar to the embodiment of FIG. 1, however, in this embodiment the gas is routed directly to a gas purifier 45 for purifying the gas pumped. The purifier removes impurities in the pumped gas and then sends it back to conduit 8 upstream of the junction with conduit 9. This allows the amount of gas supplied from the gas supply to be reduced. In this embodiment the pressure regulator 5 is located upstream of the junction between conduits 8 and 9.

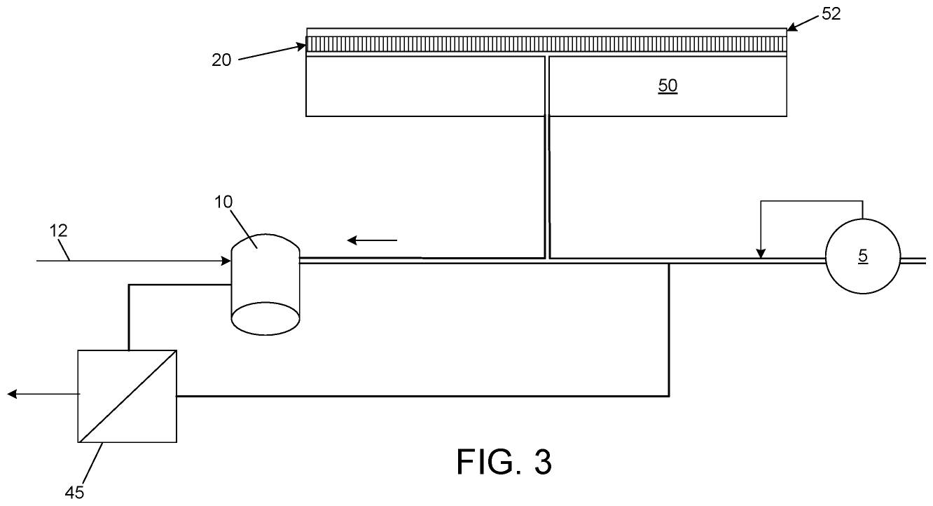

FIG. 3 shows a further embodiment, where ballast gas 12 is added to the vacuum pump 10 to improve its ability to pump gas from gas supply 40. In this embodiment the gas used for the heat transfer is Helium which has a small molecule making it difficult to pump. Ballast gas is added to vacuum pump 10 inlet such that it is pumped along with the Helium gas. In this embodiment the ballast gas is Nitrogen which has a larger molecule and is inert. The purifier 45 has a filter/sieve which removes the Nitrogen along with other impurities which are then routed to the process exhaust line. The purified Helium is then routed back to conduit 8. In this way the amount of Helium used by the system is significantly reduced.

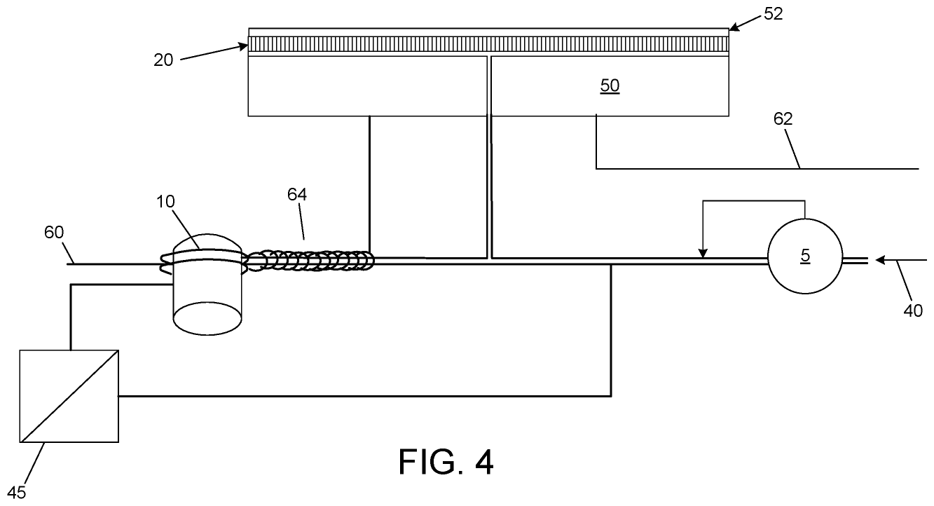

FIG. 4 shows a further embodiment comprising another way of mitigating the pumping inefficiency due to the small molecules of the heat transfer gas, such as Helium. In this embodiment, the pump and conduit 8 immediately upstream of the pump are cooled using cooling means 64. In this embodiment cooling means 64 is a heat exchanger that receives cooling fluid from a cooling system (not shown). The cooling system is also used to cool the chuck. Thus, a conduit 62 receives cooled fluid from the cooling system and routes the cooled fluid to the chuck and this fluid then travels through the chuck and to heat exchanger 64 and then back towards the cooling system at 60, where it is cooled again and sent out via conduit 62.

In this way the same chiller is used to cool the wafer (via the chuck) and the pump 10 of the gas supply system. In other embodiments there may be a separate cooling system for the vacuum pump and conduit immediately upstream of the vacuum pump 10.

In summary a gas supply apparatus is provided for supplying a gas to a chuck for improving heat conduction between the chuck and wafer, allowing a cooled chuck to more effectively cool the wafer. The gas supply apparatus has a vacuum pump dedicated for the pumping of the gas supply and not used for pumping the process exhaust. This allows mixing between the process exhaust and heat transfer gas to be inhibited allowing the heat transfer gas such as Helium to be effectively collected and re-used. Depending on the pump type, and the chosen method of ensuring there are no impurities in gas returned to the chuck, the exhaust of the pump may be connected to a collection vessel or may be connected to a purifier (molecular sieve or a cryogenic separator) for purification before returning to the tool.

Although illustrative embodiments of the invention have been disclosed in detail herein, with reference to the accompanying drawings, it is understood that the invention is not limited to the precise embodiment and that various changes and modifications can be effected therein by one skilled in the art without departing from the scope of the invention as defined by the appended claims and their equivalents.

Although elements have been shown or described as separate embodiments above, portions of each embodiment may be combined with all or part of other embodiments described above.

Although the subject matter has been described in language specific to structural features and/or methodological acts, it is to be understood that the subject matter defined in the appended claims is not necessarily limited to the specific features or acts described above.

What is claimed is:

1. A gas supply apparatus for supplying gas to a chuck within a processing chamber, said gas being for improving heat transfer between said chuck and a wafer mounted on said chuck, said gas supply apparatus comprising:
a conduit for connecting to a gas supply;
a gas supply apparatus vacuum pump, an inlet of said gas supply apparatus vacuum pump being connected to said conduit; wherein
said conduit comprises a junction connected to a further conduit said further conduit being configured to supply said gas to said chuck.

2. The apparatus according to claim 1, said conduit comprising a pressure regulator for regulating a pressure within said conduit.

3. The apparatus according to claim 2, said pressure regulator comprising a back pressure regulator for maintaining a defined pressure within said conduit upstream of said pressure regulator.

4. The apparatus according to claim 1, said apparatus comprising a gas collector for collecting said gas output from said gas supply vacuum pump.

5. The apparatus according to claim 4, said apparatus comprising a compressor for compressing said gas output from said gas supply vacuum pump prior to supplying said gas to said gas collector.

6. The apparatus according to claim 1, said apparatus comprising a purifier configured to receive said gas output from said gas supply apparatus vacuum pump.

7. The apparatus according to claim 6, said purifier being configured to separate said gas from impurities and to output purified gas to said channel upstream of said junction and to output extracted impurities to an exhaust of said apparatus.

8. The apparatus according to claim 4, said apparatus comprising a plurality of conduits for supplying gas to a plurality of chucks within a plurality of processing chambers, said gas supply apparatus comprising at least one of said gas supply apparatus vacuum pumps, each of said conduits being connected to an inlet of said at least one gas supply apparatus vacuum pump, gas output from said at least one gas supply apparatus vacuum pump being combined prior to being supplied to one of a purifier, compressor or gas collector.

9. The apparatus according to claim 1, said apparatus comprising a ballast gas supply for supplying a ballast gas to an inlet of said gas supply apparatus vacuum pump.

10. The apparatus according to claim 1, said apparatus comprising a cooler configured to cool at least a portion of said conduit downstream of said junction.

11. The apparatus according to claim 1, said apparatus comprising a cooler configured to cool said gas supply apparatus vacuum pump.

12. The apparatus according to claim 10, wherein said cooler comprises a thermal transfer device for transferring heat between a cooling system for cooling said chuck and at least one of said gas supply vacuum pump and said conduit.

13. The apparatus according to claim 1, wherein said gas supplied by said gas supply apparatus comprises Helium.

14. An apparatus comprising at least one processing chamber comprising a chuck for mounting a semiconductor wafer;
at least one processing chamber vacuum pump for evacuating said at least one processing chamber; and
a gas supply apparatus according to claim 1 for supplying gas to said chuck for providing cooling to a backside of said semiconductor wafer.

15. A method of supplying gas to a chuck within an evacuated processing chamber in order to improve heat transfer between said chuck and a semiconductor wafer mounted thereon, said method comprising:
pumping using a dedicated vacuum pump a gas from a gas supply through a conduit connected to said gas supply, said conduit comprising a junction connected to a further conduit said further conduit supply said gas to said chuck; and
regulating a pressure within said conduit to maintain a pressure of said gas at said junction at a predetermined value.
